(19) United States
(12) Patent Application Publication
(10) Pub. No.: US 2005/0074918 A1
(43) Pub. Date: Apr. 7, 2005

(54) Pad structure for stress relief

(75) Inventors: Tze-Liang Lee, Hsin-Chu (TW); Son-Ming Jeng, Hsin-Chu (TW); Shih-Chang Chen, Hsin-Chu (TW); Douglass Yu, Hsin-Chu (TW)

Correspondence Address: HAYNES AND BOONE, LLP, 901 MAIN STREET, SUITE 3100, DALLAS, TX, 75202, US

(73) Assignee: Taiwan Semicondutor Manufacturing Co.

(21) Appl. No.: 10/680,578

(22) Filed: Oct. 7, 2003

(51) Int. Cl. H01L 21/44

(52) U.S. Cl. 438/100

(57) ABSTRACT

A structure is disclosed for corners of metallic features of semiconductor integrating circuits. In the disclosed structure corner angles of all corners of metallic features that are imbedded in dielectric layers are greater than 90 degrees.

### BACKGROUND OF THE INVENTION

(1) Field of the Invention

The present invention relates generally to semiconductor integrated circuit processing and more particularly to structures of metal features with decreased stress concentration.

(2) Description of Prior Art

As currently used bonding pads, and other metallic features surrounded by dielectric layers, such as inter metallic dielectric (IMD) layers or passivation layers, are generally rectangular or square in shape. The angles at the corners of rectangles and squares are right angles. It is well known that stress concentrations exist at corners and that such stress concentrations are more severe for sharper corners. Generally, pad areas are open areas of low metal density so that the stress concentration at corners is not relieved. Excessive stress can lead to damage of the dielectric layer and failure due to consequential cracking of the dielectric layer about the pad periphery or due to pad peeling. Damage to the dielectric layer is often manifested by peeling of the bonding pads at low applied force in wire bond tests. Sources of stress about pads are prevalent during fabrication and operation of integrated circuit devices, such as directly applied mechanical stress and stress due to changes of temperature that always occur. However, the most severe stress may be generated during chemical and mechanical polishing (CMP), as indicated by the relatively frequent finding of damage to the dielectric layer after CMP. The recent trend of using low dielectric constant (low-K) dielectric materials for IMD layers exacerbates the situation. The mechanical and thermal properties of low-K dielectrics are such that they are more readily damaged by stresses than the higher K dielectric materials they are replacing.

Various procedures have been implemented to alleviate this problem of stress induced damage to IMD layers. These include improved film adhesion to strengthen the IMD layer in pad periphery areas and to retard peeling. Passivation layers that encroach bonding pads are used to retard peeling. In addition fine-tuning of the CMP recipe is used to reduce the stress resulting from this processing step. Also used are dummy pattern inserts for stress relief. A large number of bonding pads are required to transmit power, ground and impute/output signals to the chip devices and there are many other metallic features surrounded by dielectric layers in electronic devices. Failure at any one of these features implies failure of the electronic device. It is thus important to take all available steps to prevent stress-induced damage to the dielectric layers that surround bonding pads and other metallic features.

The general bonding pad structure consists of metallic layers, emanating from the terminals of the chip devices, separated by intermetal dielectric (IMD) layers that are often silicon oxide. An IMD layer separates the uppermost metallic layer from a bonding metal pattern that is formed over this IMD layer. Metallic vias pass through the IMD layers connecting the metallic layers to the bonding metal pattern. Wires are bonded to the bonding metallic pattern and to the chip package forming electrical connections between the chip and the package. A passivation layer covers the surface, except over the interior of the bonding sites, to seal the chip from contaminants and for scratch protection, and extending over the periphery of the bonding sites to retard peeling. Traditionally, metallic features, which generally are surrounded by dielectric layers, usually have ninety-degree corners. Shown in FIG. 1 is a portion of a metallic feature, 4, having a ninety-degree metallic corner, 6, surrounded by a dielectric layer, 2. For example, this could be a corner of a metallic via, since vias often have square cross-sections, or a corner of a pad, since pads are usually squares or rectangles or a corner in a conductive line since conductive lines can have right angles at turns or at its ends. This is in fact generally the case over all parts of a chip, not just the bonding pad structure. Thus, eliminating this preponderance of right angle metallic corners in a chip and replacing them with more benign structures, which have less stress concentration, could lead to significant improvement in the ability of the chip to withstand stress and is therefore a primary objective of the invention.

A technique for reducing thermally induced stress on bonding pads in semiconductor devices is disclosed in U.S. Pat. No. 5,567,655 to Rostoker et al. The reduction is accomplished by arranging the bonding pads two parallel rows, centered about a central axis a die and displaced with respect to each other, so that the two rows form a zigzag pattern. U.S. Pat. No. 5,643,830 to Rostoker et al. discloses a technique for improving power distribution to a semiconductor die while simultaneously reducing thermally induced stresses. The method involves linearly placing signal carrying bonding pads along a die axis while placing power carrying boning pads in off-axis positions. A slotted metallic die attach pad is disclosed in U.S. Pat. No. 5,075,254 to Robinson at al. for attachment of a semiconductor die to form a die assembly that demonstrates reduced die attach stress. Lin et al. in U.S. Pat. No. 6,165,886 disclose a bonding pad design, utilizing stress bumpers on the pad periphery, which can prevent passivation cracking and pad delamination during high temperature processing.

### SUMMARY OF THE INVENTION

It is a primary objective of the invention to provide a structure for corners of metallic features that are surrounded by a dielectric layer for which there is reduced stress concentration as compared with a right angle corner. It is a primary objective of the invention to provide a structure for corners of metallic features that are surrounded by a dielectric layer, which may be a low-K dielectric layer, for which there is reduced stress concentration as compared with a right angle corner It is a further primary objective of the invention to provide a structure for corners of metallic features that are surrounded by a dielectric layer, which may be a low-K dielectric layer, for which there is reduced stress concentration as compared with a right angle corner so that cracking of the dielectric layer is prevented even when such stressful process steps as CMP (chemical and mechanical polishing) are used. It is yet a further primary objective of the invention to provide a structure for corners of metallic bonding pads that are surrounded by a dielectric layer, which may be a low-k dielectric layer, for which there is reduced stress concentration as compared with a right angle corner so that damage of the dielectric layer does not occur and bonding pad peeling is prevented even when such stressful process steps as CMP are used. These objectives are accomplished by eliminating right angle corners and, instead, using corners having angles greater than 90 degrees. Square metallic features can be replaced by regular polygons having five or more sides so the corner angles are greater or equal to 108 degrees. Introducing additional sides can always eliminate right angle corners and the additional corners that are thereby introduced can all have angles greater than 90 degrees. When corner angles are greater than 90 degrees damage to the surrounding dielectric layer is inhibited.

A structure is disclosed for corners of metallic features of semiconductor integrating circuits. In the disclosed structure corner angles of all corners of metallic features that are imbedded in dielectric layers are greater than 90 degrees.

### BRIEF DESCRIPTION OF THE DRAWINGS

In the accompanying drawing forming a matenal part of this description, there is shown:

FIG. 1 shows a traditional ninety-degree metallic corner.

FIG. 2 shows metallic corners according to clipped corner embodiments of the invention.

FIG. 3 shows metallic corners according to double clipped corner embodiments of the invention.

### DESCRIPTION OF THE PREFERRED EMBODIMENTS

The basic concept of the invention is to provide a structure in which the angles of corners of metallic features that are surrounded by a dielectric layer are larger than ninety degrees. At such corners there is reduced stress concentration as compared with a right angle corner. Traditionally there are a large number of right angle corners in metallic features that are surrounded by dielectric layers and in preferred embodiments of the invention right angle corners are replaced by corners of larger angles. Large angle corners are particularly important for corners of metallic features that are surrounded by low-K dielectric layers since low-K dielectric materials are more susceptible to damage than traditional dielectric materials. Damage of the dielectric is more prevalent when such stressful process steps as CMP (chemical and mechanical polishing) are used and large angle corners can prevent dielectric damage even when CMP is used.

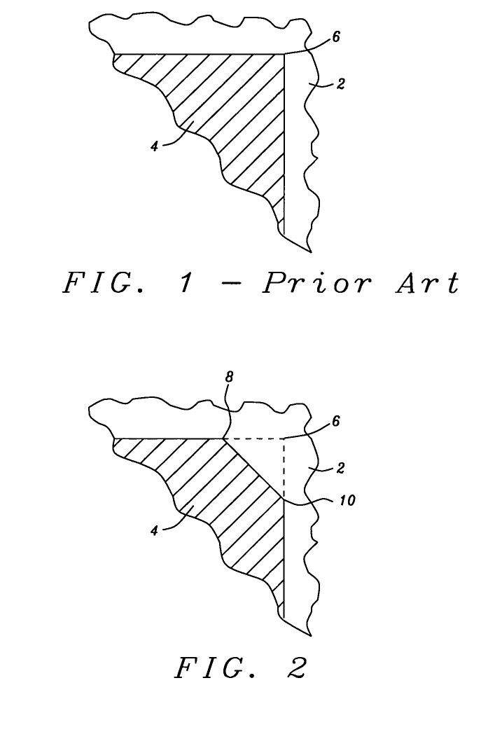

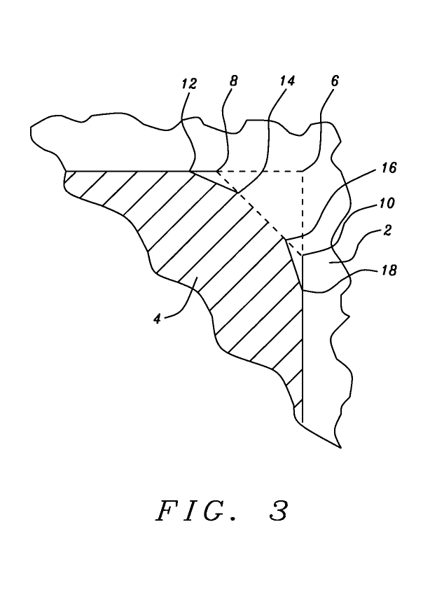

FIG. 2 illustrates a basic pattern for clipped corner structures, which are preferred embodiments of the invention. Clipped corners are metallic features that are surrounded by a dielectric layer, for which there is reduced stress concentration as compared with a right angle corner. The clipped corner structure, as well as the structure for other preferred embodiments of the invention, is most easily achieved by patterning the feature to achieve the clipped corner configuration using traditional patterning techniques, such as photolithography. No actual clipping is required, the nomenclature being figurative. The configuration achieved by replacing right angle corners by two corners with angles greater than 90 degrees, as shown in FIG. 2, is denoted a clipped corner configuration. Traditionally, metallic features, which generally are surrounded by dielectric layers, usually have ninety-degree corners. Shown in FIG. 2 is a portion of a metallic feature, 4, surrounded by a dielectric layer, 2 and, instead of a traditional ninety-degree metallic corner, 6, as shown by the dashed lines in FIG. 2, there are, according to clipped corner preferred embodiments of the invention, two metallic corners, 8 and 10. The corners 8 and 10 each have angles greater than ninety degrees and thus less stress concentration than a ninety-degree corner. When the angles of the corners 8 and 10 are equal they are 135 degrees. In most preferred clipped corner embodiments of the invention, denoted equal angle clipped corner embodiments, the angles of both corners are about 135 degrees and the configuration is referred to as an equal angle clipped corner configuration. Right angle corners are prevalent in traditional structures. For example, the portion of a metallic feature of FIG. 2 could be a portion of a metallic via, since vias traditionally have square cross-sections, or the edges of metal filled trenches that traditionally have rectangular shapes or a corner of a pad, since traditionally pads are usually squares or rectangles or a portion of a conductive line since conductive lines can have right angles at turns or at its ends. Eliminating right angle metallic corners of a chip and replacing them with the more benign clipped corner structures of FIG. 2, which having larger angle corners have less stress concentration, could thus lead to significant improvement in the ability of the chip to withstand stress.

Metallic features can be composed from any of the conductive materials and formed by any of the techniques used in semiconductor processing. Doped polysilicon, metal suicides, Al, Cu, W are commonly used conductive materials, at times in combination, for metallic features. Dielectric materials traditionally used include silicon oxides, doped glasses such as PSG or BPSG, silicon nitrides and silicon oxynitrides. These materials have dielectric constants, K, greater than about 3.5, Young's moduli between about 40 and 100 Gpa and temperature coefficients of expansion (TCE) between about 0.5 and 2 um/mC. Values of Young's modulus and TCE for conductive materials that are used in metallic features can be in the vicinity of 100 Gpa and 2 um/mC, respectively. Higher values of Young's modulus are preferred and lowered stress is achieved during temperature excursions when the TCE of the dielectric material and conductive material are more nearly the same. Young's moduli of traditional dielectric materials are substantial and they possess TCE values that do not differ very much from that of the conductive materials. These materials can reasonably well withstand many of the stressful situations encountered in processing and operation even with ninety-degree corners. Larger angle corners are needed, to reduce stress concentration, only if process steps producing excessive stress are used. For example, CMP is known to especially stressful. Also important, is that open corners that do not have material above them have less mechanical strength than when they are covered by the next level. So that when CMP is performed at a level, the open corners, that is the corners of that level, are more susceptible to damage by CMP than the closed corners of the levels below. It is thus possible to use the high angle corner structures of the invention mainly in levels on which CMP, or other high stress step, is to be performed.

Although there is a risk of dielectric layer damage from CMP even for traditional dielectric materials and higher angle corners of the structures of the invention should be used, the risk of dielectric layer damage is considerably greater for the relatively new low K dielectric materials. There is a trend at present to utilize low K materials, generally having K values lower than 3, as dielectric layers. These low k dielectrics provide the important advantage of substantially lower capacitance than if traditional dielectric materials are used. This advantage, however, comes at a cost. Low K materials have low Young's moduli, less than about 18 Gpa and high TCE, larger than about 15 um/mC, much larger than that of the conductive materials. It is thus important, when using low K dielectric layers, to limit stress concentrations that lead to dielectric layer damage such as cracking. Utilizing clipped corner embodiments of the invention, it is found that stress concentrations are limited efficiently and effectively, so that dielectric layer damage is not observed even after CMP.

The clipped corner procedure always leads to increased corner angles, even if the angle of the original corner is not ninety degrees. Double clipped corners embodiments of the invention, shown in FIG. 3, are based on this fact. Dashed lines in FIG. 3 are included only as aids in depicting how the shapes of double clipped corners embodiments, termed double clipped corner configurations, are achieved. Double clipped corners embodiments of the invention are useful if corner angles greater than 135 degrees are required. As seen from FIG. 3, clipping the corners 8 and 10, which, as described above, arise when a right angle is clipped, attains the double clipped corners shape. The angles of the corners 12 and 14, attainable by clipping corner 8, are each larger than the angle of corner 8 and, similarly, the angles of the corners 16 and 18, attainable by clipping corner 10, are each larger than the angle of corner 10. In most preferred double clipped corner embodiments of the invention, denoted equal angle double clipped corner embodiments, the angles of corners 12, 14, 16 and 18 are about equal, and the shapes achieved are denoted equal angle double clipped corner configurations. Angles of corners 8 and 10 in equal angle clipped corner embodiments are about 135 degrees so the angles of corners 12, 14. 16 and 18 are about 157.5 degrees in equal angle double clipped corner embodiments. Double clipped corner embodiments of the invention result in larger corner angles and thus lower stress concentration at the corners. It is possible that only at some of the corners will it be necessary to reduce stress concentration to the degree achieved by equal angle double clipped corner embodiments. For example, equal angle double clipped corner embodiments may be required only for corners in layers having low K dielectrics and upon which CMP is to be performed and otherwise it may be sufficient to use clipped corner embodiments.

Other preferred embodiments utilize a generalization of the clipped corner and double clipped corner preferred embodiments. n-fold clipped corner embodiments are structures for metal features in which 2ⁿ corners can be thought to arise from a right angle corner in n clipping generations, and the shapes achieved are denoted n-fold clipped corner configurations. When the 2ⁿ corner angles are about equal, in which case the embodiments are denoted n-fold equal angle clipped corner embodiments and the shapes, n-fold equal angle clipped corner configurations, they are about ((2ⁿ⁺¹−1)/2ⁿ) 90 degrees, which approaches 180 degrees as n increases. A O-fold equal angle clipped corner is just a right angle, a 1-fold equal angle clipped corner, the clipped corner referred to above, is two corners each of 135 degrees and a 2-fold equal angle clipped corner, the double clipped corner referred to above, is four corners each of 157.5 degrees. Similarly, a 3-fold equal angle clipped corner, which can be thought to arise from a double clipped corner by clipping each of its four corners, is eight corners each of 168.75 degrees. Stress concentrations are smaller about larger corner angles, so that there is reduced stress about n-fold clipped corners for larger n. It is possible that only at some corners will it be necessary to reduce stress concentration to the extent that n-fold equal angle clipped corner embodiments with n greater than 2 need be utilized and otherwise it may be sufficient to use clipped corner or double clipped corner embodiments.

In other preferred embodiments of the invention an increase in corner angle of polygonal metallic features is achieved by increasing the number of sides of the polygon. The corner angle of a traditionally square metallic feature, for example a bonding pad, can be increased by using a pentagon or hexagon instead. Since the corner angle of a regular polygon of m sides is 180(1-2/m) degrees, the corner angle is thus increased from 90 to 108 degrees, upon using a pentagon (m=5) instead of a square and from 90 to 120 degrees upon using a hexagon (m=6) instead of a square. The corner angle of an octagon is 135 degrees, the same as the corner angle of clipped corner embodiments, and the corner angle of double clipped corner embodiments, 157.5 degrees, is attained for an m=16 polygon. Larger corner angles correspond to smaller stress concentrations so dielectric layers surrounding metallic polygons with more sides are less susceptible to damage. It is possible that only at some of the metallic polygons will it be necessary to reduce stress concentration to the degree achieved by polygons with many sides. For example, m=16 polygons may be required only for corners in layers having low K dielectrics and upon which CMP is to be performed and otherwise it may be sufficient to use lower m polygons.

While the invention has been particularly shown and described with reference to the preferred embodiments thereof, it will be understood by those skilled in the art that various changes in form and detail may be made without departing from the spirit and scope of the invention.

1. A structure for corners of metallic features of semiconductor integrating circuits, comprising:
Corner angles of all corners of metallic features, imbedded in dielectric layers, which are greater than 90 degrees.

2. The structure of claim 1 wherein said dielectric layer is composed of materials from the set: silicon oxide, silicon nitride, silicon oxynitride, PSG, BPSG.

3. The structure of claim 1 wherein said dielectric layer is a composite of dielectric layers.

4. The structure of claim 1 wherein said dielectric layer is a low-K dielectric material.

5. The structure of claim 1 wherein said metallic feature is a composed of materials from the set: doped polysilicon, metal suicides, Al, Cu, W.

6. The structure of claim 1 wherein said metallic feature is a feature from the set: via, trench, pad, line.

7. A structure for corners of metallic features of semiconductor integrating circuits, comprising:
Corners of all metallic features, imbedded in dielectric layers, which are formed in n-fold clipped corner configurations, with n being greater than 0.

8. The structure of claim 7 wherein said dielectric layer is composed of materials from the set: silicon oxide, silicon nitride, silicon oxynitride, PSG, BPSG.

9. The structure of claim 7 wherein said dielectric layer is a composite of dielectric layers.

10. The structure of claim 7 wherein said dielectric layer is a low-K dielectric material.

11. The structure of claim 7 wherein said metallic feature is a composed of materials from the set: doped polysilicon, metal silicides, Al, Cu, W.

12. The structure of claim 7 wherein said metallic feature is a feature from the set: via, trench, pad, line.

13. The structure of claim 7 wherein said n-fold clipped corner configurations of corners of metallic features of a level are n-fold equal angle clipped corner configurations, with n equal or greater than one, when said dielectric layer of said level is composed of a low-K dielectric material and no CMP step is done on said level.

14. The structure of claim 7 wherein said n-fold clipped corner configurations of corners of metallic features of a level are n-fold equal angle clipped corner configurations, with n equal or greater than 2, when said dielectric layer of said level is composed of a low-K dielectric material and a CMP step is done on said level.

15. The structure of claim 7 wherein said n-fold clipped corner configurations of corners of metallic features of a level are n-fold equal angle clipped corner configurations, with n equal or greater than one, when said dielectric layer of said level is composed of a material of the set: silicon oxide, silicon nitride, silicon oxynitride, PSG, BPSG and a CMP step is done on said level.

16. A structure for metallic features of semiconductor integrating circuits, comprising:
shapes of all metallic features imbedded in dielectric layers, that may be formed as squares, are configured as m-sided regular polygons.

17. The structure of claim 16 wherein said dielectric layer is composed of materials from the set: silicon oxide, silicon nitride, silicon oxynitride, PSG, BPSG.

18. The structure of claim 16 wherein said dielectric layer is a composite of dielectric layers.

19. The structure of claim 16 wherein said dielectric layer is a low-K dielectric material.

20. The structure of claim 16 wherein said metallic feature is a composed of materials from the set: doped polysilicon, metal silicides, Al, Cu, W.

21. The structure of claim 16 wherein said metallic feature is a pad.

22. The structure of claim 16 wherein m of said m-sided regular polygon is at least equal to 8 when said metallic features are on a level where said dielectric layer is composed of a low-K dielectric material and no CMP step is done on said level.

23. The structure of claim 16 wherein m of said m-sided regular polygon is at least equal to 16 when said metallic features are on a level where said dielectric layer is composed of a low-K dielectric material and a CMP step is done on said level.

24. The structure of claim 16 wherein m of said m-sided regular polygon is at least equal to 8 when said metallic features are on a level where said dielectric layer is composed of a material of the set: silicon oxide, silicon nitride, silicon oxynitride, PSG, BPSG and a CMP step is done on said level.

25. A method for forming corners of metallic features of semiconductor integrating circuits, comprising:
forming all corners of metallic features imbedded in dielectric layers so that corner angles are all greater than 90 degrees.

26. The method of claim 25 wherein said dielectric layer is composed of materials from the set: silicon oxide, silicon nitride, silicon oxynitride, PSG, BPSG.

27. The method of claim 25 wherein said dielectric layer is a composite of dielectric layers.

28. The method of claim 25 wherein said dielectric layer is a low-K dielectric material.

29. The method of claim 25 wherein said metallic feature is a composed of materials from the set: doped polysilicon, metal silicides, Al, Cu, W.

30. The method of claim 25 wherein said metallic feature is a feature from the set: via, trench, pad, line.

31. A method for forming corners of metallic features of semiconductor integrating circuits, comprising:
Forming all corners of metallic features imbedded in dielectric layers in n-fold clipped corner configurations, with n being greater than 0.

32. The method of claim 31 wherein said dielectric layer is composed of materials from the set: silicon oxide, silicon nitride, silicon oxynitride, PSG, BPSG.

33. The method of claim 31 wherein said dielectric layer is a composite of dielectric layers.

34. The method of claim 31 wherein said dielectric layer is a low-K dielectric material.

35. The method of claim 31 wherein said metallic feature is a composed of materials from the set: doped polysilicon, metal silicides, Al, Cu, W.

36. The method of claim 31 wherein said metallic feature is a feature from the set: via, trench, pad, line.

37. The method of claim 31 wherein said n-fold clipped corner configurations of corners of metallic features of a level are n-fold equal angle clipped corner configurations, with n equal or greater than one, when said dielectric layer of said level is composed of a low-K dielectric material and no CMP step is done on said level.

38. The method of claim 31 wherein said n-fold clipped corner configurations of corners of metallic features of a level are n-fold equal angle clipped corner configurations, with n equal or greater than 2, when said dielectric layer of said level is composed of a low-K dielectric material and a CMP step is done on said level.

39. The method of claim 31 wherein said n-fold clipped corner configurations of corners of metallic features of a level are n-fold equal angle clipped corner configurations, with n equal or greater than one, when said dielectric layer of said level is composed of a material of the set: silicon oxide, silicon nitride, silicon oxynitride, PSG, BPSG and a CMP step is done on said level.

40. A method for forming metallic features of semiconductor integrating circuits, comprising:
Forming all metallic features imbedded in dielectric layers, that may be formed as squares, as m-sided regular polygons.

41. The method of claim 40 wherein said dielectric layer is composed of materials from the set: silicon oxide, silicon nitride, silicon oxynitride, PSG, BPSG.

42. The method of claim 40 wherein said dielectric layer is a composite of dielectric layers.

43. The method of claim 40 wherein said dielectric layer is a low-K dielectric material.

44. The method of claim 40 wherein said metallic feature is a composed of materials from the set: doped polysilicon, metal silicides, Al, Cu, W.

45. The method of claim 46 wherein said metallic feature is a pad.

46. The method of claim 40 wherein m of said m-sided regular polygon is at least equal to 8 when said metallic features are on a level where said dielectric layer is composed of a low-K dielectric material and no CMP step is done on said level.

47. The method of claim 40 wherein m of said m-sided regular polygon is at least equal to 16 when said metallic features are on a level where said dielectric layer is composed of a low-K dielectric material and a CMP step is done on said level.

48. The method of claim 40 wherein m of said m-sided regular polygon is at least equal to 8 when said metallic features are on a level where said dielectric layer is composed of a material of the set: silicon oxide, silicon nitride, silicon oxynitride, PSG, BPSG and a CMP step is done on said level.
